(19) United States
(12) Patent Application Publication
(10) Pub. No.: US 2011/0287942 A1
(43) Pub. Date: Nov. 24, 2011

(54) FAULT CURRENT SUPERCONDUCTIVE LIMITER

(75) Inventors: Salvatore Imparato, Bologna (IT); Antonio Morandi, Bologna (IT)

(73) Assignee: Alma Mater Studiorum Universita DiBologna, Bologna (IT)

(21) Appl. No.: 12/998,356

(22) PCT Filed: Oct. 14, 2009
(86) PCT No.: PCT/IT2009/000466

§ 371 Date: Aug. 3, 2011

(30) Foreign Application Priority Data
Oct. 14, 2008 (IT) RM2008A000547

(51) Int. Cl. H01L 39/02; H01L 39/12; H02H 7/00

(52) U.S. Cl. 505/211; 505/150; 361/19

(57) ABSTRACT

The present invention concerns a superconducting fault current limiter (1) comprising a rectifier bridge (2) made of active devices (3a, 3b, 3c, 3d) connected to a circuit that is to be protected, said rectifier bridge (2) comprising four branches connected by means of four nodes (4, 5, 6, 7), wherein a first node (4) and a second node(5), not adjacent to said first node (4), are connected to said circuit that is to be protected (12, 13), characterized in that it comprises a central branch (8) connected from the third node (6) to the fourth node (7) of said rectifier bridge (2), comprising or consisting of at least one circuit element comprising an inductive component, whose aim is to reduce the amplitude of the ripple of the current through said central branch (8), and a nonlinear superconducting resistive component, having:
a first operating condition, wherein the current through said central branch (8) does not exceed a given threshold value, so that said at least one circuit element, comprising a nonlinear superconducting resistive component, is in the superconducting state; and
a second operating condition, wherein the current through said central branch (8) exceeds a given threshold value, so that said at least one circuit part, comprising a nonlinear superconducting resistive component, is in the non-superconducting state, thus offering a resistive behavior.

The present invention concerns a superconducting fault current limiter (SFCL).

More specifically, the invention deals with a superconducting fault current limiter for the protection of electric network or power systems, suitable to operate in direct current conditions for alternate current applications.

As it is well known, the provision of a fault current limiting device in modern electric systems is a fundamental requirement to assure the reliable management and the preservation of modern electric power systems.

The operating experience shows that the occurrence of a short circuit fault, whose effects are extremely dangerous for both the functionality of the components and the stability of the whole system, is not infrequent.

The measures commonly used to face this problem, such as high impedance transformers, serially connected air core reactors and network splitting, introduce permanent losses and limit the efficient operation of the power system.

Research investments are then needed to develop fault current limiter devices which are able to limit the fault current without affecting the power system during ordinary operating conditions.

Among all possible concepts of fault current limiters, those based on superconducting materials show ideal characteristics. As a matter of fact, a superconducting fault current limiter (SFCL) is a device that has a negligible impedance in normal operating conditions and is able to switch spontaneously to a high impedance state when the current flowing therein overcomes a given value, that is designated as the fault threshold.

The introduction of such a device into the electric power system involves, among others, the following advantages:
it allows an improved and flexible power supply quality without jeopardizing the safety of the network in case of failure;
it limits the first peak of the fault current thus reducing the stress on the components and allowing a less expensive design;
its design can be carried out in such a manner as to ensure a symmetrical component of short circuit current consistent with the interruption capability of existing switches, thus avoiding their replacement in case of expansion of the network;
the limiting action is self-activating and so reliable;
the recovery of the low impedance state after the fault extinction is spontaneous and does not require any restore action.

Depending on the layout and the operating principle, a superconducting fault current limiter may be classified as resistive type, rectifier type (also referred to as diode or thyristor bridge type), shielded magnetic core type, or saturated magnetic core type limiters. A thorough review of possible SFCL concepts presently under test is given in Noe and Steurer [2007].

In last decades many superconducting fault current limiter prototypes, based on high temperature superconducting materials (HTS) both of first generation (BSCCO, Bismuth Strontium Calcium Copper Oxide) and of second generation (YBCO, Yttrium Barium Copper Oxide), have been fabricated to demonstrate the technical feasibility.

More recently, the use of the Magnesium Diboride (MgB2), a superconductor that is commercially available at competitive cost and quantity, has been also considered.

Some SFCL prototypes for medium voltage applications have reached a pre-industrial stage of development. They have been optimized with respect to most engineering issues, like cryogenics, electric insulation, mechanical strength and other, and have been successfully submitted to long term field tests in the medium voltage mains.

Nevertheless, in order to allow the effective penetration of said devices in the marketplace, some issues mainly related to the alternate current losses and the related operating cost must still be solved.

In the following description, some types of limiters are examined in detail, starting from the resistive type ones.

A resistive type SFCL is based on the transition from the superconducting to the normal (high resistivity) conducting state which occurs when the current exceeds a defined critical value.

Such SFCL is typically made up of a superconducting wire or tape wound in such a way as to obtain an as low as possible inductance (bifilar coil or transposed pancake).

The superconducting wire, or tape, directly carries the alternate current flowing in the circuit to be protected which gives rise to a power dissipation therein (AC losses). In fact, a superconductor wire or tape shows no loss only if it carries a purely direct current). Said losses require a very expensive refrigeration, in order not to increase the temperature of the superconductor elements, and thus imply very high operating costs of the limiter. Moreover, a practical superconducting wire or tape is made up of superconducting filaments or layers in contact with a normal conductor, like silver, copper or similar, to avoid the damage hazard due to local heating (hot spots). The presence of the normal conductor layer lowers the resistance of the superconducting tape or wire, once its transition to the normal state has been effected. Therefore, in order to get a satisfying limiting effect, a long length of wires or tapes is required, with a consequent increase of the overall power dissipated by the limiter due to the alternate current losses.

In order to minimize the hazards of local overheating while minimizing at the same time the length of the tape and the consequent losses, many different superconducting fault current limiters were proposed in which the transition from the superconducting state to the normal one is assisted by the onset of a magnetic field. Such a superconducting fault current limiter is described in the WO 94/03955 and U.S. Pat. No. 7,180,396 patents. Said superconducting fault current limiters require a complex geometry of the superconducting part and the use of several parallel or series connected normal coils. Moreover, during the normal operating conditions, an alternate current anyway flows in the superconducting tape or wire which causes high cooling costs to be incurred.

Another interesting type of superconducting fault current limiter is the rectifier type superconducting fault current limiter. This is made of a inductor series connected to a DC voltage source and embedded in a full-wave diode or thyristor rectifier bridge which is connected to the protected load. The inductor may conveniently consist of a superconducting material coil in order to avoid resistive losses.

In normal operating conditions, the inductor is bypassed by the current of the protected circuit which flows through the diodes or thyristors. When this mains current exceeds the current flowing in the coil, two of the four diodes/thyristors are reverse biased, so that the coil is automatically inserted in series to the protected circuit. Such a bridge type superconducting fault current limiter, with the inductor consisting of a superconducting material coil, was originally proposed by Boenig and it is described in the U.S. Pat. No. 4,490,769.

The use of thyristors rather than diodes allows, in addition to the limiting capability, the possibility to break the fault current through an active control circuit connected to the gates of the thyristors.

A technical problem of the above mentioned current limiter is the construction of the direct current voltage source, which is needed to obtain a purely direct current (DC) through the coil. In order to avoid this problem, it was proposed by Boening to modify the original device by removing both the DC source and the need to use a superconducting material to implement the inductor, as described in the U.S. Pat. No. 5,726,848.

A technical problem of the current rectifier bridge type limiters above described is that the absence of the direct voltage source, which is necessary to set the DC current in the coil, implies that the above mentioned limiters affect the network even during the normal load variations occurring during the normal operation, thereby causing voltage drops to the users.

In order to maintain the disturbance on the voltage within the limits prescribed by the international standard (EN 50160), the value of the inductance to be used cannot exceed a proper limit, consequently the limiting capability of the device is strongly reduced, or the short circuit fault cannot be limited to values relevantly lower than the ones that would be reached without the limiter.

Moreover, both in absence and in presence of the DC voltage source, the limiting effect is obtained by introducing an inductance series connected to the protected circuit. The equivalent impedance of the network during the short circuit fault is prevalently inductive, and this implies the following drawbacks:

a. a delay in the zero crossing of the current and a greater difficulty to extinguish the electric arc between the opening poles of the circuit breakers;

b. a decrease of the dynamic stability of the network during the fault.

It is evident that these technical limits are onerous for the eventual inefficiencies in the supply of the electrical current, as well as for economic reasons.

On the basis of the above, it is an object of the present invention to provide a superconducting fault current limiter of resistive type for alternate current applications, suitable to operate in direct current condition.

It is a further object of the present invention to offer a reduced thermal load to the cooling system, both during normal operation (by operating in direct current) and during the fault occurrence (by means of conventional resistors connected in parallel).

It is therefore a specific object of the present invention a superconducting fault current limiter including a rectifier bridge made up of a suitable number of active devices connected to the protected circuit, said rectifier bridge having four branches which form four nodes, in which a first node and a second node, not consecutive to said first node, are connected to said protected circuit, characterized by having a central branch connected between the third node and the fourth node of said rectifier bridge, comprising or consisting of at least one circuit element including an inductive component, suitable to reduce the ripple of the current flowing through said central branch, and a superconducting non linear resistive component which has:
a first operating condition, wherein the current through said central branch is below a pre-established threshold value, so that said at least one circuit element, which includes said superconducting non linear resistive component, is in a superconducting state; and
a second operating condition, wherein the current flowing through said central branch is higher than said pre-established threshold value, so that said at least one circuit element, which has said superconducting non linear resistive component, is not in a superconducting state, thus exhibiting a resistive behavior.

Again in accordance with the present invention, said at least one circuit component can include an inductor and a superconducting nonlinear resistor.

In accordance with the present invention yet, said inductor can be made of superconducting material and it may be set in order not to have a transition to said second operating condition.

In another aspect of this invention, said inductor and said superconducting nonlinear resistor can be advantageously series connected.

Furthermore, in accordance with the present invention, said inductor can be placed in a suitable position near said superconducting nonlinear resistor in order to aid, by means of the generated magnetic field, the transition from said first operating condition to said second operating condition.

Again in accordance with the present invention, said at least one circuit element can comprise an inductor made up of superconducting material, which comprises said inductive component and said superconducting nonlinear resistive component.

In accordance with the present invention yet, said superconducting fault current limiter can include at least one conventional resistor parallel connected to the said at least one circuit element which comprises said superconducting nonlinear resistive component, in order to drain a portion of the current flowing through said at least one circuit element in said second operating condition, so reducing the thermal load and the recovery time of said current limiter.

Furthermore, in accordance with the present invention, said at least one conventional resistor can be connected to said first node and to said second node of said rectifier bridge.

In advantageous manner, in accordance with the invention, said limiter can comprise a conventional resistor connected to said third node and to said fourth node of said rectifier bridge.

Again in accordance with the invention, said superconducting fault current limiter can include a conventional resistor connected in parallel to said at least one circuit element which comprises said superconducting nonlinear resistive component.

In accordance with the present invention yet, the superconducting material of said at least one circuit element, which includes a superconducting nonlinear resistive component, can be selected among the following ones: magnesium diboride (MgB2); Bismuth Strontium Calcium Copper Oxide (BSCCO); Yttrium Barium Copper Oxide (YBCO).

Further, in accordance with the invention, said limiter can comprise a cooling system for cooling said at least one circuit element comprising said superconducting nonlinear resistive component.

Advantageously, always in accordance to the invention, said active devices can include diodes or thyristors, in the latter case said superconducting fault current limiter can include control means for said thyristors.

In accordance with the invention yet, said rectifier bridge can comprise said active devices, each one provided with an anode and a cathode, connected as below described:
a first active device has the anode connected to said first node and the cathode connected to said third node;
a second active device has the anode connected to said fourth node and the cathode connected to said second node;
a third active device has the anode connected to said fourth node and the cathode connected to said first node; and
a fourth active device has the anode connected to said second node and the cathode connected to said third node.

In accordance with the invention yet, said limiter can comprise a cooling systems for cooling said superconducting nonlinear resistive component.

Advantageously, in accordance with the invention, said protected circuit can be selected among the following ones: an electric feeder line, connected to said first node, an electrical load, connected to said second node; an electrical feeder line outgoing from an electrical power generator; feeder lines of auxiliary services of electrical power plants; bus coupling of two or more electrical distribution networks; busbar connections; shunt of reactors for the limitation of the fault current; power transformer feeders; electric feeders outgoing from busbar; combination of different superconducting devices, such as superconducting cables; connections of distributed power generation units; closure of ring networks.

In order to explain the principle of the present invention, some accompanying drawings related to its preferred embodiments are below reported for the purpose of illustration, exemplification and description, although they are not intended to be exhaustive:

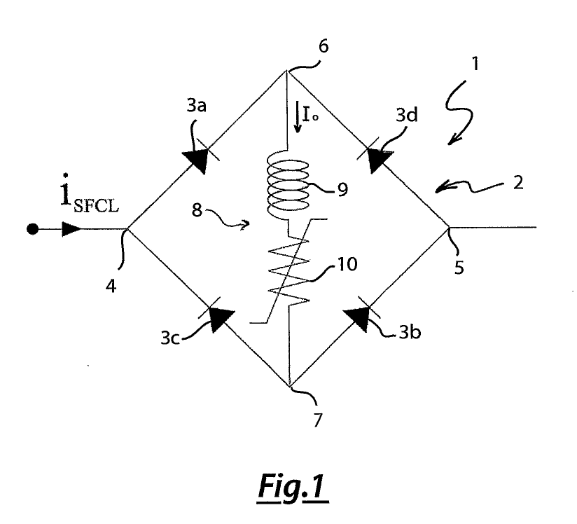

FIG. 1 shows the circuit scheme of a first embodiment of a superconducting fault current limiter in accordance with the present invention;

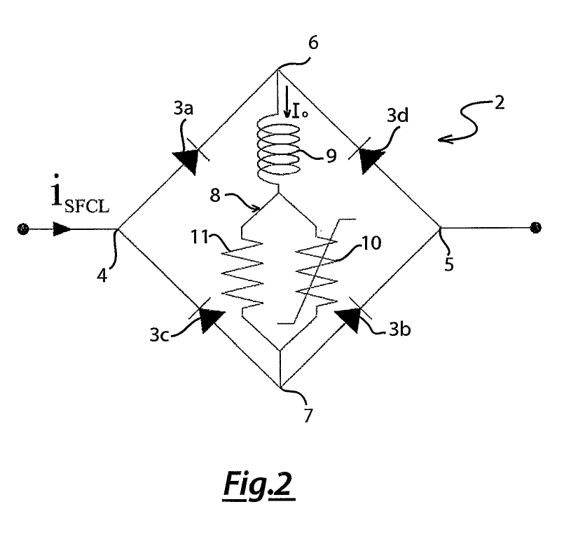

FIG. 2 shows the equivalent circuit scheme of a second embodiment of a superconducting fault current limiter in accordance with the present invention;

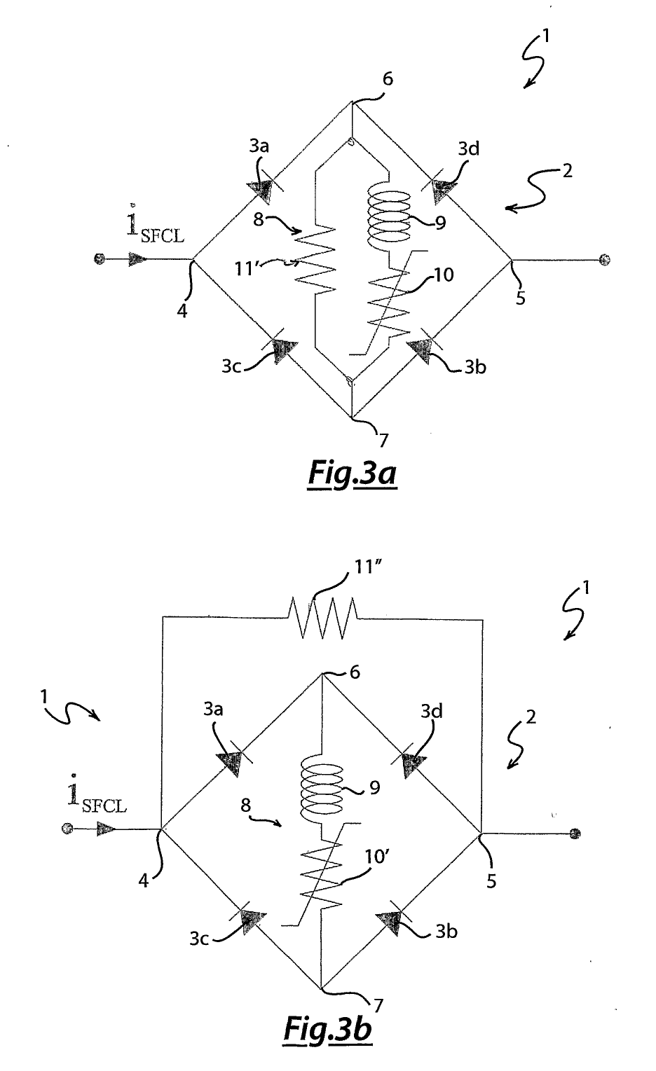

FIG. 3a shows the equivalent circuit scheme of a third embodiment of a superconducting fault current limiter in accordance with the present invention;

FIG. 3b shows the equivalent electrical circuit scheme of a fourth embodiment of a superconducting fault current limiter in accordance with the present invention;

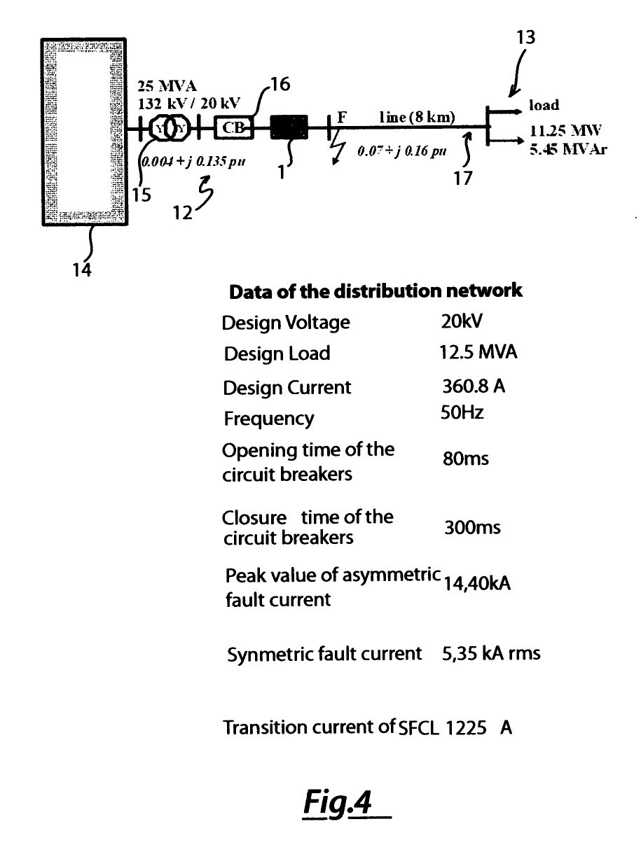

FIG. 4 shows a connection scheme for the application of the current limiter in the accordance with the present invention to a three-phase electric power supply system;

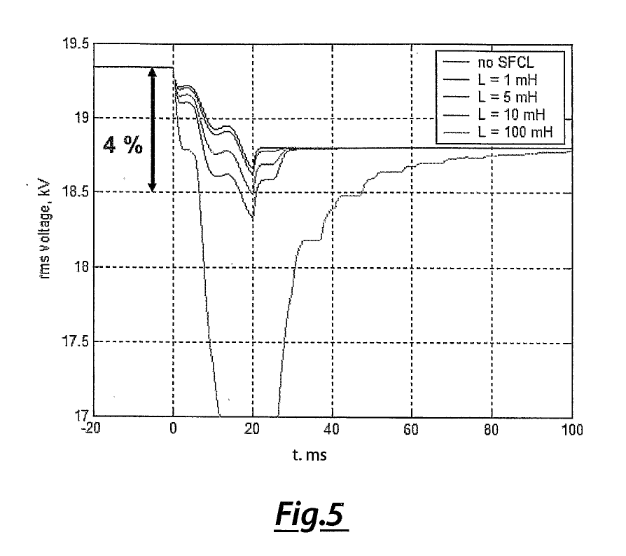

FIG. 5 shows the time evolution of the network voltage for different values of the inductance;

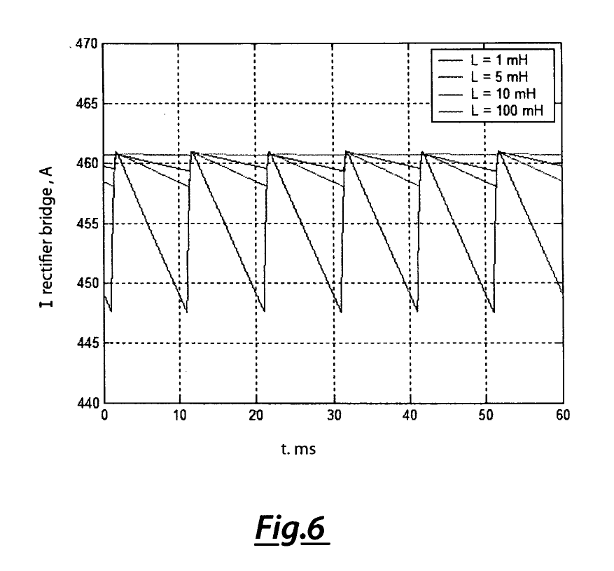

FIG. 6 shows the current of the internal branch of the rectifier bridge of the superconducting fault current limiter, according to the embodiment of FIG. 1, during normal operating conditions for different values of the inductance;

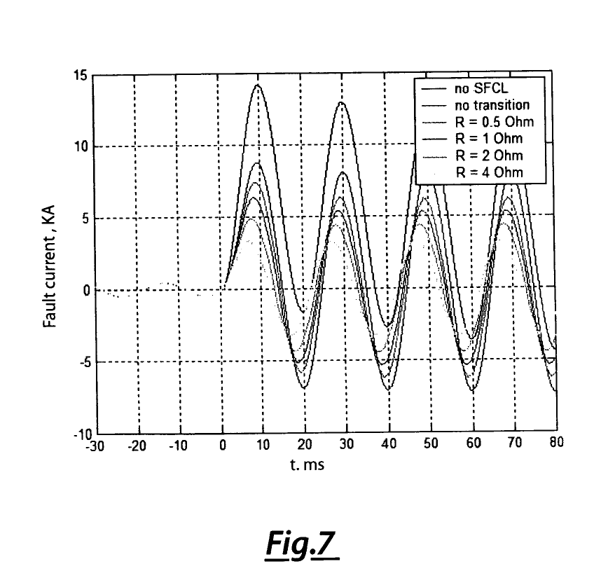

FIG. 7 shows the fault current according to the embodiment of FIG. 1, for different values of the resistance R; and

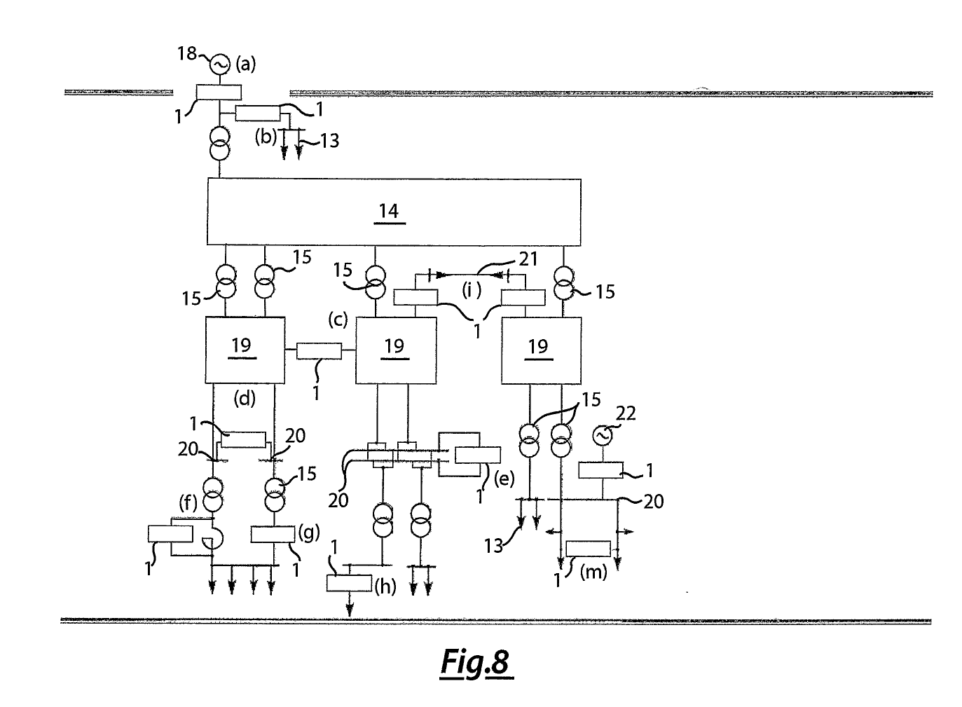

FIG. 8 shows some possible applications of the superconducting fault current limiter in accordance with the present invention.

In the various figures, similar parts are marked with the same reference number.

In FIG. 1 a first embodiment of the superconducting fault current limiter 1 according to the invention, connected in series to an electric circuit to be protected (not shown in the figure) can be observed. The embodiment shown includes a rectifier bridge 2, with four active devices 3a, 3b, 3c e 3d that in this case are diodes.

Said rectifier bridge 2 has four branches, each one comprising one of said diodes 3a, 3b, 3c e 3d. Said branches are connected by means of four nodes 4, 5, 6 and 7. Said protected circuit can be connected to the first node 4 and to the second node 5.
The connections of the diodes 3a, 3b, 3c e 3d to the rectifier bridge 2 are made as follows:
diode 3a: anode connected to node 4, cathode connected to node 6;
diode 3b: anode connected to node 7, cathode connected to node 5;
diode 3c: anode connected to node 7, cathode connected to node 4;
diode 3d: anode connected to node 5, cathode connected to node 6.

The current limiter 1 includes a further central branch 8 connected to said node 6 and to node 7. Said central branch 8 comprises an inductor 9 and a superconducting nonlinear resistor 10 serially connected to one another.

The fault current limiter 1, according to the invention, utilizes therefore the combination of the resistive limiter and the rectifier bridge limiter concepts, as it will be described later on.

The superconducting non linear resistor 10 has a resistive behavior, in case of transition of its superconducting material from the superconducting state to the not superconducting one.

Two operating conditions are identified in the following description: an operating condition, named “normal”, in which the superconducting material of the nonlinear resistor 10 is in the superconducting state thanks to a suitable cooling system (e.g. a cryogenic bath) and an operating condition, named “active”, in which the superconducting material of the nonlinear resistor 10 undergoes a transition from the superconducting state to the normal not superconducting one.

In normal operating condition, the current flowing through the superconducting nonlinear resistor 10 is given by the envelope of the peaks of the sinusoidal current flowing through the fault current limiter 1. In particular, said current, designated as i_{SFCL}(t) in the figure, consists of a constant value with a ripple superposed, whose fundamental harmonic component has a frequency that is the twice the operating frequency of the protected circuit which the fault current limiter in connected to.

This is due to arrangement of diodes 3a, 3b, 3c and 3d. The amplitude of said ripple component decreases with the value of the inductance L of the inductor 9. Therefore, the higher is the inductance L of the inductor 9 the lower is the ripple, and consequently the lower are the AC losses of the superconductor. In other words, the aim of the inductive component of the central branch 8 is to reduce the size of the ripple and the AC losses.

Of course, the value of the inductance L of the inductor 9 should be as high as possible, provided that the fault current limiter 1 does not affect the system (electric line or broadly the protected circuit to which it is connected during normal operating conditions.

This implies that, for example in case of short circuit, the inductance of the inductor 9 cannot be as high as it is needed to limit the fault current at an acceptable level, for instance in a short circuit event.

In steady state the inductor 9 carries a DC current, designated as I₀ in the figures, which splits up in two equal portions flowing through the couples of diodes 3a-3b and 3c-3d respectively. A decay of the current (decreasing portion of the ripple) occurs due to the voltage drop on the diodes 3a, 3b, 3c e 3d. When the current drops below the value of the current of the protected circuit, the inductor becomes series connected to it and the current increases up to the peak of the sinusoid where the decay begins.

Let a positive half-wave of the current i_{SFCL}(t) passing through the fault current limiter 1 be considered. Since the diodes 3a, 3b, 3c e 3d are all forward biased said instantaneous current i_{SFCL}(t) bypasses said central branch through which said current I₀ flows.

The total voltage of the fault current limiter 1 is given by the overall voltage drop on the couple of diodes 3a e 3d (that is equivalent to that applied to the couple of diodes 3c e 3b), which is negligible with respect to the voltage of the protected circuit, therefore, the fault current limiter 1 offers a practically zero impedance.

Therefore, according to what was mentioned above, a current i_{3a-3b}=I₀/2+i_{SFCL}/2 flows through diodes 3a and 3b, whereas a current i_{3c-3d}=I₀/2−i_{SFCL}/2 flows through diodes 3c and 3d.

Said superconducting nonlinear resistor 10 is able to undergo a transition from said normal state to said active state when the current exceeds a fixed threshold value, thus acquiring a resistive behavior with resistance R.

The fault current limiter 1 is hence provided with a suitable limiting capability thanks to the transition of the superconducting nonlinear resistor 10 and consequently to the introduction of a resistance (in addition to an inductance) in series to the circuit during a fault condition, such a resistance being generated just due to the transition of the material of the concerned non linear resistor 10 from a superconducting condition to a normal conduction condition, which occurs when a current higher than a certain pre-established current flows through it.

Since generally the equivalent impedance of a power system during a short circuit has a dominant inductive component, the fault current limiter 1 according to the invention does not make the dynamic stability of the system worse and moreover facilitates the extinction of the electric arc occurring between the poles of the circuit breakers on opening thereof.

Therefore, as one may observe, the fault current limiter 1 according to the invention adds a resistive component to the equivalent impedance (otherwise predominantly inductive) of the system during the short circuit condition and does not make the dynamic stability of the system worse and moreover facilitates the extinction of the electric arc occurring between the poles of the circuit breakers on opening thereof.

Let in fact the positive half wave of the current i_{SFCL}(t) be considered. If this current exceeds the value of the DC component I₀ due to a fault causing a short circuit current, the current i_{3c-3d}=I₀/2−i_{SFCL}/2 would change its sign and would not be allowed because diodes 3c e 3d are reverse biased. Therefore, the whole current I₀/2+i_{SFCL}/2=i_{SFCL}/2+i_{SFCL}/2=i_{SFCL} flows through the inductor 9 and the superconducting nonlinear resistor 10.

At a pre-established fault current, the superconducting nonlinear resistor 10 switches from the normal operating condition to the active operating condition because of one or more of the following events:

(a) the current of the protected circuit exceeds a given threshold value;

(b) the magnetic field generated by inductor 9 exceeds a given threshold value;

(c) the temperature of the superconducting material exceeds a given threshold value;

(d) both the events (a) e (b) occur;

(e) both the events (a) e (c) occur;

(f) both the events (b) e (c) occur;

(g) all the three events (a), (b) e (c) occur.

When said superconducting nonlinear resistor 10 switches to its not superconducting condition, it behaves as a resistor, thereby limiting the fault current.

Therefore, the transition of the superconducting material of the superconducting nonlinear resistor 10 is exploited to produce the desired fault current limiting effect, differently from the well-known technology in which the superconducting materials are only employed in order to reduce the energy losses.

Moreover, as it is well-known, the superconducting materials work optimally in direct current conditions, and the inductor 9 in combination with the bridge arrangement of the active devices 3a, 3b, 3c e 3d, assures in fact a direct current operation condition without the use of any other active device, such as external current sources or similar.

Possibly, active devices 3a, 3b, 3c and 3d can also be realized as thyristors, so that the concerned limiter can operate both as a circuit breaker and as a current limiter, provided that suitable means are provided for controlling the gates of the thyristors.

The described fault current limiter 1 allows to limit a fault current in a single-phase electric circuit or power system. For a three-phase electric current limiter system, three fault current limiters 1, one per each phase, are needed.

Again in accordance with this embodiment, said inductor 9 may be made of superconducting material and may be sized in such a way as not to undergo any transition and to remain in said normal operating condition, therefore in the superconducting state even if a fault occurs. This allows to reduce the overall losses in the concerned limiter 1.

FIG. 2 shows a further embodiment of the superconducting fault current limiter 1 in accordance with the present invention, wherein the central branch 8 further comprises a conventional resistor 11 connected in parallel to the superconducting nonlinear resistor 10. Such an embodiment is applicable only if the inductance and the superconducting nonlinear resistance of the central branch are fabricated by means of two distinct windings or devices. Said conventional resistor 11 allows to drain a portion of the current which flows through said superconducting nonlinear resistor 10 during a fault condition, so that the thermal load and consequently the recovery time of said fault current limiter 1 are reduced.

In other words, the technical effect of said conventional resistor 11 is to reduce the overheating of the superconducting material of the said superconducting nonlinear resistor 10, thus avoiding possible damages and reducing the time necessary to switch back from the active operating condition to normal operating one.

FIG. 3a shows a third embodiment of the fault current limiter 1 in accordance with the invention, in which a conventional resistor 11′ is connected to said not-consecutive third node 6 and fourth node 7 of said rectifier bridge 2. This embodiment is applicable even if the inductance and the superconductive nonlinear resistance of the central branch are not realized by means of two distinct windings or devices. Also in this case, said conventional resistor 11′ allows to drain a portion of the current which would flow through said superconducting nonlinear resistor 10 during a fault condition, thereby reducing the thermal load and consequently the recovery time of said fault current limiter 1.

The embodiment of FIG. 3a has a further advantage with respect to the one shown in FIG. 2. In fact, should also inductor 9 be superconducting, it is possible to use just two instead of three current wires to connect the superconducting parts to other parts of the circuit operating at room temperature, thus reducing the thermal load of the cooling system.

FIG. 3b shows another embodiment of the fault current limiter 1 in accordance with the invention, wherein a conventional resistor 11″ is connected to said not-consecutive first node 4 and second node 5 of said rectifier bridge 2, namely in parallel to the whole limiter 1.

Finally, it is possible to conceive a further embodiment of the present invention, wherein the inductive effect of inductor 9 and the nonlinear superconducting resistive effect of resistor 10 are combined in single inductor (winding, coil), made of superconducting material having:
a first operating condition, in which the current through said current limiter 1 is below a fixed threshold value, so said inductor 9 is in the superconducting state; and
a second operating condition, in which the current through said current limiter 1 is above said fixed threshold value, so that the superconducting material of said inductor 9 switches from the superconducting state to not-superconducting one, thus creating a resistive effect.

In this way, the inductor 9 and the superconducting nonlinear resistor 10 are integrated in a single component.

Said superconducting nonlinear resistor 10 and said inductor 9, in the case that it is made up of superconducting material, may be made of any available superconducting material, regardless of its own critic temperature and of the pressure conditions required for its operation.

Moreover, again in accordance with the invention, the fabrication of the said superconductive nonlinear resistor 10 and of said inductor 9, in the case that the latter is made of superconducting material and it is integrated with said superconducting nonlinear resistor 10, may comprise any configuration, production process or technology, e.g. windings with any layout made by means of tapes, filaments or layers, bifilar windings, alternate pancake windings, windings with magnetic field assisted quench, superconducting meanders, superconducting thin film, bulks, etc.

Further, it is well known that, in order to avoid a partial transition of the superconductor, a magnetic field can be applied to it (so as to avoid the damage process named “hot spots”). Therefore, in a preferred embodiment, inductor 9 can be placed in a suitable position near to said superconducting nonlinear resistor 10 in order to assist, by means of the generated magnetic field, an optimum transition from said superconducting condition to said not superconducting condition.

FIG. 4 shows a possible application of the fault current limiter 1 which is connected to a three phase intermediate voltage distribution system 12 feeding an electric load 13. Of course, one fault current limiter 1 must be connected at each phase of the system.

In FIG. 4, the main characteristics and parameters of the distribution system 12 are shown.

As it can be seen, the electric power distribution system 12 is connected to a 132 kVolt transmission system 14 by means of a transformer 15, having a scaliong factor from 132 kVolt to 20 kVolt.

The transformer 15, the circuit breaker 16, the superconducting fault current limiter 1 in the present embodiment and the load 13 are all series connected by means of an electric feeder 17, whose length is 8 km.

The next figures show the operating features of the superconducting fault current limiter 1 in the embodiment of FIG. 1 and the connection of FIG. 4.

In FIG. 5, the voltage transient resulting from a 80% increase of the load due to ordinary load insertion (f.i. insertion of a big production plant) is shown as a function of various inductance values.

It can be seen from FIG. 5 that, when the inductance of inductor 9 is lower than 5 mH, the voltage sag is lower than 4%, as required by the EN 50160 standard. The inductance value L=5 mH for inductor 9 is then chosen as a design inductance value of the superconducting winding.

In FIG. 6 the current of the superconductor is plotted for different values of the inductance L of the inductor 9. It can be seen that the amplitude of the ripple decreases with an increase of the inductance. At L=5 mH, the current in the superconductor is equal to 459.5±1.4 A.

In FIG. 7, the waveform of short circuit current due to a three-phase fault is plotted for L=5 mH and different values of the resistance reached upon completion of the transition. It can be observed that, assuming a resistive behaviour of the superconductive material with a resistance value R=4 Ohm, the short-circuit current is about 25% of the value that would be reached in absence of current limiter 1. The value R=4 Ohm is then chosen as design value for the superconducting coil.

Finally, FIG. 8 shows the possible connections of the limiter (1) listed below:

(a) a feeder line from generator 18;

(b) power supply for station auxiliaries;

(c) coupling of distribution networks 19;

(d) busbar coupling 20;

(e) shunting reactors for limitation of fault current;

(f) feeder lines from a transformer 15;

(g) busbar connection/feeder 20;

(h) combination with other superconducting devices, such as superconducting cables 21;

(i) coupling local generating units 22;

(l) closure of ring networks.

An advantage of the present invention is to be able to achieve a satisfactory limiting capability without affecting the electric power system during its ordinary operating condition. In the conventional rectifier bridge type fault current limiter these two features cannot be contemporaneously achieved. Moreover, the limiter in accordance with the present invention adds a resistance to the short circuit impedance of the network, so making easier the extinguishing of the electric arc and avoiding a worsening of the dynamic stability of the network during the fault condition.

An advantage of the present invention is that the superconducting nonlinear resistor operates in direct current steady state and without external source device.

A further advantage is that the described superconducting fault current limiter is not only applicable to the electric power system but also to the electrical on-board systems for marine, land and space vehicles as well as for electrical railway and transportation systems.

The foregoing description of the preferred embodiments of the invention have been presented for purpose of illustration and description. It is not intended to be exhaustive or to limit the invention to the precise form disclosed, and obviously many modifications and variations are possible in the light of the above teaching, anyway reserving the scope and the right of protection as defined by the claims appended hereto.

1. Fault current limiter (1) comprising: a rectifier bridge (2) made up of active devices (3a, 3b, 3c, 3d) that is connected to a protected circuit, said rectifier bridge (2) having four branches forming four nodes (4, 5, 6, 7), wherein a first node (4) and a second node (5) not adjacent to said first node (4) are connected to the circuit that is to be protected (12, 13), characterized in that it comprises a central branch (8) connected between the third node (6) and the fourth node (7) of said rectifier bridge (2), comprising or consisting of at least one circuit element including an inductive component, adapted to reduce the amplitude of the ripple of the current flowing through said central branch (8), and a nonlinear superconducting resistive component, having:
a first operating condition, wherein the current flowing through said central branch (8) is below a given threshold value, so that said at least one circuit element, comprising a nonlinear superconducting resistive component, is in a superconducting state; and
a second operating condition, wherein the current flowing through said central branch (8) exceeds said fixed threshold value, so that said at least one circuit element, comprising a nonlinear superconducting resistive component, is not in a superconducting state, so offering a resistive behavior.

2. The limiter (1) as described in claim 1, characterized by the fact that said at least one circuit element comprises an inductor (9) and a superconducting nonlinear resistor (10).

3. The limiter (1) as described in claim 2, wherein said inductor (9) is made of superconducting material and is designed in order not to undergo the transition to said second operating condition.

4. The limiter (1) as described in claim 2, wherein said inductor (9) and said superconducting nonlinear resistor (10) are series connected.

5. The limiter (1) as described in claim 2, wherein said inductor (9) is placed near to the nonlinear superconducting resistor (10) in order to assist the transition from said first operating condition to said second operative condition by means of the magnetic field generated.

6. The limiter (1) as described in claim 1, wherein said at least one circuit element comprises an inductor that is made of superconducting material having both inductive and nonlinear superconducting resistive components.

7. The limiter (1) as described in claim 1, characterized in that it comprises at least one conventional resistor (11, 11′, 1″) connected in parallel to said at least one circuit element comprising said superconducting nonlinear resistive component, in order to drain a portion of the current flowing through said at least one circuit element in said second operating condition, thus reducing the thermal load thereon and the recovery time of said limiter (1).

8. Limiter (1) as described in claim 7, wherein said at least one conventional resistor (11′) is connected to said first node (4) and to said second node (5) of said rectifier bridge (2).

9. Limiter (1) as described in claim 7, characterized in that it comprises a conventional resistor (11′) connected to said third node (6) and to said fourth node (7) of said rectifier bridge (2).

10. Limiter (1) as described in claim 7, characterized in that it comprises a conventional resistor (11) parallel connected to said circuit element comprising a superconducting nonlinear resistive component.

11. Limiter (1) as described in claim 1, wherein the superconducting material of said at least one circuit element comprising said superconducting nonlinear resistive component is chosen among: Magnesium Diboride (MgB2); Bismuth Strontium Calcium Copper Oxide (BSCCO); Yttrium Barium Copper Oxide (YBCO).

12. Limiter (1) as described in claim 1, characterized in that it comprises a cooling system for cooling said at least one circuit element comprising said superconducting nonlinear resistive component.

13. Limiter (1) as described in claim 1, wherein said active devices comprise diodes (3a, 3b, 3c e 3d).

14. Limiter (1) as described in claim 1, wherein said active devices comprise thyristors as well as means for controlling said thyristors.

15. Limiter (1) as described in claim 1, wherein said rectifier bridge (2) comprises said active devices each one provided with an anode and a cathode, connected as below described:
a first active device (3a) has the anode connected to said first node (4) and the cathode connected to said third node (6);
a second active device (3b) has the anode connected to said fourth node (7) and a cathode connected to said second node (5);
a third active device (3c) has the anode connected to said fourth node (7) and the cathode connected to said first node (4); and—a fourth active device (3d) has the anode connected to said second node (5) and the cathode connected to said third node (6).

16. Limiter (1) as described in claim 1, characterized in that it comprises a cooling means for cooling said superconducting nonlinear resistive component.

17. Limiter (1) as described in any one of the previous claims, wherein said circuit to be protected is chosen among: an electric feeder line (12), connected to said first node (4), an electric load (13), connected to said second node (5); a feeder line (8) from a generator; feeder lines for power station auxiliaries; network couplings (19); a busbar coupling (20); shunting of current limiting reactors; feeder lines (15) from transformers; systems containing other superconducting devices, such as superconducting cables (21); connection of distributed generating units (22); closure of ring networks.
